(19) United States
(12) Patent Application Publication
(10) Pub. No.: US 2018/0286287 A1
(43) Pub. Date: Oct. 4, 2018

(54) SYSTEM AND METHODS FOR TRAINING PHYSICIANS TO PERFORM ABLATION PROCEDURES

(71) Applicant: Covidien LP, Mansfield, MA (US)

(72) Inventor: SHARIF RAZZAQUE, BOULDER, CO (US)

(21) Appl. No.: 15/937,565

(22) Filed: Mar. 27, 2018

Related U.S. Application Data
(60) Provisional application No. 62/477,515, filed on Mar. 28, 2017.

(51) Int. Cl. G09B 23/32; G09B 23/28; G09B 9/00; G01R 33/02

(52) U.S. Cl. CPC G09B 23/32; G09B 23/286; G06T 17/00; G01R 33/02; G09B 9/00

(57) ABSTRACT

Systems and methods for performing simulated ablation procedures are disclosed. A system may include a simulated ablation probe, a simulated imaging device, a phantom configured to be engaged by the simulated ablation probe and the simulated imaging device, the phantom representing an anatomical feature, and a workstation in electrical communication with the simulated ablation probe, the simulated imaging device, and the phantom. The workstation is configured to display an image including the representation of the anatomical feature represented by the phantom. The image further includes data associated with the position of the simulated ablation probe relative to the representation of the anatomical feature represented by the phantom.

### CROSS-REFERENCE TO RELATED APPLICATION

The present application claims the benefit of, and priority to, U.S. Provisional Patent Application No. 62/477,515 filed on Mar. 28, 2017, entitled “SYSTEM AND METHODS FOR TRAINING PHYSICIANS TO PERFORM ABLATION PROCEDURES,” the entire contents of which are hereby incorporated by reference in their entirety.

### BACKGROUND

### Technical Field

The present disclosure is directed to systems and methods of performing simulated surgical procedures which may include identifying and navigating to targets in an organ (e.g., a liver) of an artificial patient for treatment of tumors during simulated surgical procedures.

### Description of Related Art

Training a physician to perform needle ablation generally requires equipment such as an ultrasound or computed tomography (CT) scanner, a microwave ablation generator, and an ablation tool, each of which may have a limited useful life. Training is traditionally performed on either a live animal, ex-vivo tissue (e.g., harvested organs such as a bovine or pig liver), or an ultrasound phantom which, during training, is punctured with a needle and imaged. Prior to training, these tools are set-up in a training surgical suite or an operational surgical suite taken out of service. The use of industry training facilities adds additional costs such as maintenance of the facility and transportation of personnel and/or equipment to and from the facility. Similarly, placing the operational surgical suite back in service requires sterilization and replacement of select equipment. Known systems and methods of training which include the use of live animals or ex-vivo tissue additionally require disposal of biological waste.

With the exception of live animal testing, use of ex-vivo tissue and phantoms do not permit accurate visualization or an experience similar to those experienced when using these tools to treat a human or other live animal suffering from a treatable disease. While new commercial systems generally make targeting easier, clinicians still must remember certain procedures to be performed during the ablation which include: putting a guide (where the ablation antenna trajectory intersects with the ultrasound scan or CT image slice) on the target before advancing the antenna into tissue; scanning the entire trajectory before advancing the antenna to avoid critical structures; confirming the antenna position with an ultrasound wand; mentally offsetting the navigation ablation zone to match the position of the antenna relative to the indicated location of the antenna versus where the navigation system predicted it to be; and scanning the ablation zone before applying energy.

As a result of the continued development of navigation systems, concurrent development or modification of operation instructions, which must be memorized in part or in whole by an operator, have brought about a need for advanced training methods.

### SUMMARY

According to embodiments of the present disclosure, a system for performing simulated ablation procedures is disclosed. The system includes a simulated ablation probe, a simulated imaging device, a phantom configured to be engaged by the simulated ablation probe and the simulated ultrasound imaging device, the phantom representing an anatomical feature, and a workstation in electrical communication with the simulated ablation probe, the simulated ultrasound imaging device, and the phantom. The workstation is configured to generate and display an image including the representation of the anatomical feature represented by the phantom. The image further includes data associated with the pose of the simulated ablation probe relative to the representation of the anatomical feature represented by the phantom.

In aspects, the simulated imaging device may be either a simulated ultrasound imaging device or a simulated CT scanner.

According to aspects, a portion of the phantom may be configured to approximate the shape of the anatomical feature while the anatomical feature is functioning.

In aspects, the workstation may generate the image based on the phantom and a pre-existing data set associated with the organ.

According to aspects, the workstation may receive imaging position information associated with the pose of the simulated imaging device relative to the phantom and, based on the imaging position information, generates a first updated image.

In aspects, the workstation may receive probe position information associated with the pose of the simulated ablation probe relative to the phantom and, based on the probe position information, generate a second updated image.

According to aspects, the workstation may be configured to generate a third updated image including an ablation region formed along the anatomical feature based on the probe position information in response to user input indicating that ablation is to be performed by the simulated ablation probe.

In aspects, the workstation may receive user input including at least one energy property selected from the group consisting of voltage, current, power, and impedance and, based on the at least one energy property and the probe position information, and an energy delivery duration, generates a third updated image including an ablation region formed along the representation of the anatomical feature.

According to aspects, the workstation may receive phantom position information indicating a position of the phantom relative to a base and, based on the position of the phantom, generates a third updated image.

In aspects, the phantom may be configured to change in shape so as to approximate the shape of the organ acting within a body.

According to aspects, an EM sensor may be disposed along a distal portion of both the simulated ablation probe and the simulated imaging device, and an electromagnetic (EM) field generator may be disposed in proximity to the phantom, the EM field generator configured to generate an EM field, and the workstation configured to receive position information from the EM sensors disposed on the simulated ablation probe and the simulated imaging device.

In aspects, an EM sensor may be disposed along the phantom and, in response to the generated EM field, the EM field generator may be configured to receive position information from the EM sensor disposed along the phantom.

According to aspects of the present disclosure, a workstation for simulating ablation procedures is disclosed. The workstation includes a processor, and a memory coupled to the processor, the memory having instructions stored thereon which, when executed by the processor, cause the workstation to, receive position information of a simulated imaging device and a simulated ablation probe positioned relative to a phantom associated with an organ, generate an image including a representation of the organ associated with the phantom based on the position information of the simulated imaging device and the simulated ablation probe, and

transmit a signal to cause the image to be displayed on a display associated with the workstation, The image includes a representation of the simulated ablation probe relative to the representation of the organ associated with the phantom.

In aspects the memory may further having stored thereon instructions that, when executed by the processor, cause the processor to receive position information of the phantom relative to a fixed point on the phantom. The generating may include generating the image based on the position information of the phantom.

According to aspects, the receiving may include continuously receiving the position information of the simulated imaging device, the simulated ablation probe, and the generating may include continuously generating the image based on the continuously received position information of the simulated imaging device, the simulated ablation probe and the phantom.

In aspects of the present disclosure, a method of simulating a surgical procedure with an ablation training system is disclosed. The method includes receiving device information from a simulated ablation probe and a simulated imaging device, receiving position information of the simulated ablation probe and the simulated imaging device relative to a phantom, determining a pose of the simulated ablation probe and the simulated imaging device relative to the phantom, and generating a display including a visual representation of the position of a simulated ablation probe relative to an anatomical feature based on the pose of the simulated ablation probe and the simulated imaging device.

According to aspects, generating a display may include overlaying a navigation plan onto the visual representation of the simulated ablation probe relative to the anatomical feature.

In aspects, overlaying the navigation plan may include overlaying navigational aids onto the visual representation of the simulated ablation probe relative to the anatomical feature.

According to aspects, the method may include displaying a visual representation of the anatomical feature in response to receiving user input to ablate a target region.

### BRIEF DESCRIPTION OF THE DRAWINGS

The accompanying drawings, which are incorporated in and constitute a part of the specification, illustrate embodiments of the disclosure and, together with a general description of the disclosure given above, and the detailed description of the embodiment or embodiments given below, server to explain the principles of the disclosure.

FIG. 1 is a schematic diagram of an ablation training system, in accordance with embodiments of the present disclosure;

FIG. 2 is a schematic block diagram of an illustrative embodiment of a computing device that may be employed in various embodiments of this system, for instance, as part of the system or components of FIG. 1;

FIG. 3 is a flowchart showing an illustrative method for training a clinician to perform a surgical procedure with the ablation training system of FIG. 1, in accordance with embodiments of the present disclosure;

FIG. 4 is an illustration of a user interface which may be presented on the display of the training system of FIG. 1 including simulated ultrasound images, in accordance with embodiments of the present disclosure;

FIGS. 5A and 5B depict an exemplary user interface that may be presented on the display of the training system of FIG. 1 including simulated images of a lung in a first and second state;

FIG. 6 is a flow diagram depicting a method of simulating targeted ablation; and

FIG. 7 is another illustration of a user interface which may be presented on the display of the training system of FIG. 1 including simulated CT scan images and simulated ultrasound images, in accordance with embodiments of the present disclosure.

### DETAILED DESCRIPTION

The present disclosure is directed to systems and methods of training physicians or clinicians through the use of a live, intra-operative, ultrasound or CT simulator. Such systems and methods may be implemented to facilitate and/or make accessible the training of clinicians in remote locations where training may otherwise be impractical.

The systems and methods of the present disclosure present clinicians with training systems capable of performing simulated microwave ablation surgeries. The training systems include a workstation and a simulator. The workstation receives signals from a simulated ablation probe, simulated ultrasound wand, and the simulator. The signals received from the simulated ultrasound wand may, simulate a variety of images captured by varying ultrasound imaging techniques. Such simulated ultrasound images may be generated to emulate laparoscopic, open surgical, endoscopic, bronchoscopic, cardiac, transvaginal, transrectal, or percutaneous ultrasound imaging.

In embodiments, signals may be received by the workstation from known imaging devices, such as CT imaging devices, cone-beam CT imaging devices, magnetic resonance imaging (MM) devices, and fluoroscopy imaging devices, which indicate the position of the respective imaging device relative to the simulator. Additionally, or alternatively, imaging signals may be received by the workstation from one or more of the above-mentioned imaging devices when imaging is performed on the workstation (e.g., intra-operative CT scan data may be transmitted to the workstation and subsequently analyzed by the workstation to determine the position of the simulated ablation probe relative to the simulator). For purposes of clarity, reference will be made to systems incorporating ultrasound imaging devices, though it is contemplated that any of the above-mentioned imaging systems may be simulated during simulated procedures. Based on the signals, the workstation generates visual and/or audio feedback (e.g., a two-dimensional or three-dimensional images, a video stream, and/or audible tones). The simulator includes a synthetic tissue mass or phantom (e.g., a synthetic liver, synthetic torso, and the like) which may be acted upon by a clinicians with a simulated ablation probe and a simulated imaging device (e.g., a simulated ultrasound wand) during simulated surgeries. The workstation, simulator, phantom, simulated ablation probe, and simulation imaging device, as well as the associated components thereof, may be directly or indirectly in electrical communication (either via wired or wireless connection) with the workstation, or to one another. For purposes of clarity, the term “phantom” will refer to the physical apparatus approximating an organ, whereas the terms “anatomical feature” or “anatomical representation” represent the generated ultrasound image of the organ represented by the phantom. Reference numerals in the corresponding figures will identify the anatomical feature with the same reference numeral as the phantom.

During a simulated surgical procedure, the clinician causes the simulated ablation probe and simulated ultrasound wand to contact the phantom as the clinician performs a simulated surgical procedure. In embodiments, the simulator has an electromagnetic (EM) field generator forming part of an EM tracking system 109 which tracks the position and orientation (also commonly referred to as the “pose”) of EM sensors disposed on the simulated ablation probe and the simulated ultrasound wand. The simulator then transmits the information received by the EM tracking system 109 to the workstation which determines the pose of the instruments in three-dimensional space relative to the phantom. Examples of suitable or similar EM tracking systems include the AURORA™ system sold by Northern Digital, Inc. Similarly, systems and methods for identifying and tracking instruments electromagnetically, commonly referred to as electromagnetic navigation (“EMN”) are discussed in greater detail in U.S. Patent Application Publication No. 2017/0135760, entitled “Systems and Methods for Ultrasound Image-Guided Ablation Antenna Placement, the contents of which are hereby incorporated in their entirety. Likewise, EM tracking systems 109 similar to those of the present disclosure are disclosed in U.S. Pat. No. 6,188,355 and published PCT Application Nos. WO 00/10456 and WO 10/67035, the entire contents of each of which being hereby incorporated by reference in their entirety.

It will be understood that, while the present application discusses tracking positions and orientations of simulated surgical instruments and simulated imaging instruments (e.g., simulated ablation probes and simulated ultrasound wands) relative to a simulator, instrument tracking should not be limited to such. In embodiments, the pose of the simulated surgical instruments and simulated imaging instruments may be tracked by optical tracking sensors such as NDI Medical's Polaris® Optical Tracking Systems and optical tracking systems produced by OptiTrack®. Additionally, or alternatively, inertial measurement units (IMUs) including accelerometers and/or gyroscopes, acoustic tracking, as well as other known tracking systems and sensors for detecting and determining the pose of the simulated surgical imaging instruments and/or the simulated imaging instruments may be used in embodiments of the present disclosure. For purposes of clarity, reference will be made throughout the present disclosure to tracking of simulated surgical instruments and simulated imaging instruments with an EM tracking system.

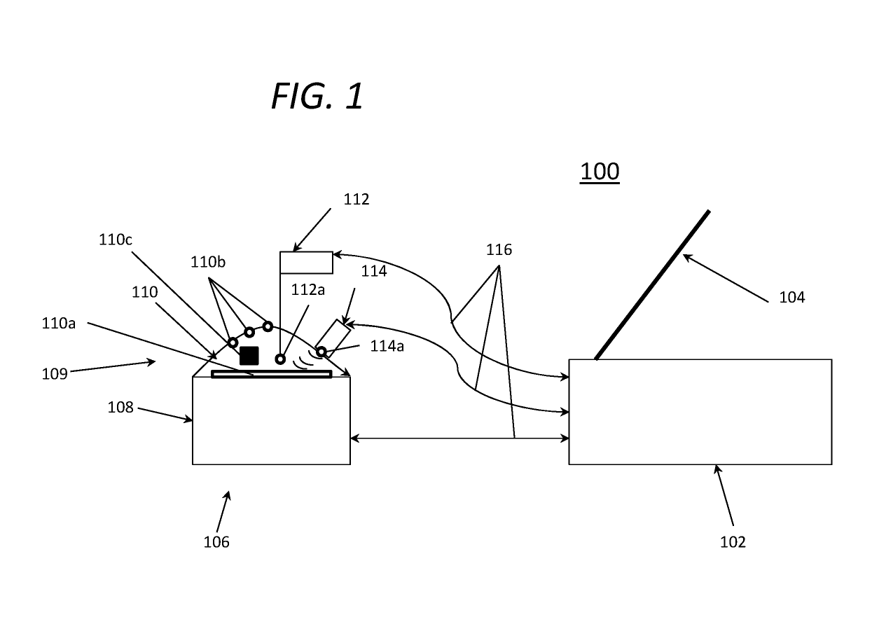

FIG. 1 is a schematic diagram of an ablation training system, generally referred to as training system 100. The components and configuration of the training system 100 of FIG. 1 are provided for illustrative purposes only, and should not be seen as limiting the present disclosure. As discussed above, the training system 100 is configured to be engaged by one or more clinicians during a simulated surgical procedure to enable performance of a virtual surgical procedure. While performing simulated surgical procedures, clinicians are able to acquaint themselves with the training system 100, including the components forming the training system 100, thereby increasing their comfort while using the training system 100 and learned techniques for operating the training system 100.

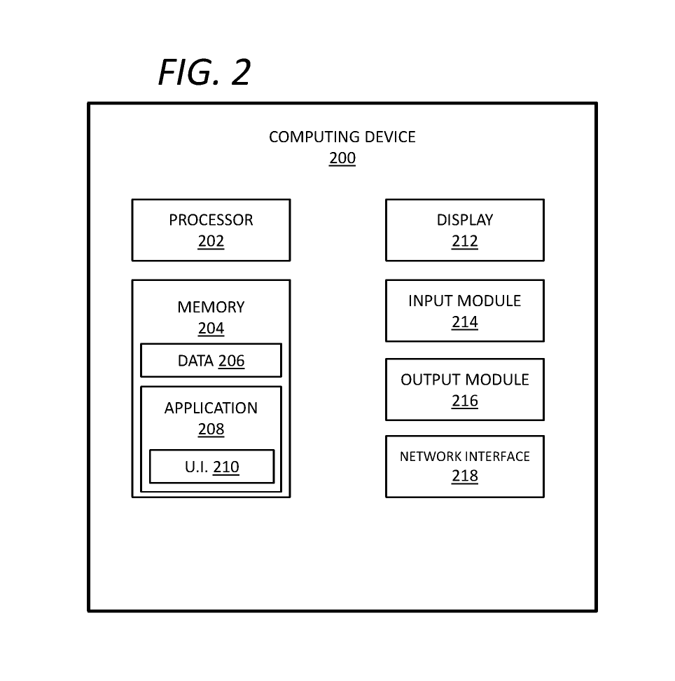

The training system 100 includes a workstation 102 having a display device or display 104 connected thereto, and a simulator 106 in communication with the workstation 102 (via either wired, or wireless communication). A simulated microwave ablation probe 112 and a virtual ultrasound wand or simulated ultrasound wand 114 may be coupled to the workstation 102 via one or more wired or wireless connections, herein referred to as connections 116. While the application is not to be limited to the simulation of microwave ablation or ultrasound and/or CT imaging, for purposes of clarity the present application will be discussed with reference generally to microwave ablation and/or CT imaging. It is contemplated, however, that the present disclosure may simulate ablation procedures which include delivering electrical energy to tissue, delivering or removing thermal energy (cryoablation), microwave ablation, and the like. The workstation 102, simulator 106, simulated microwave ablation probe 112, and simulated ultrasound wand 114 may include some or all of the components discussed with respect to a computing device 200, described in detail below with respect to FIG. 2.

In embodiments, a simulated electrosurgical generator (not shown) may be in communication with the workstation 102 and the simulated ablation probe 112. The simulated electrosurgical generator may be configured to receive input information from the clinician such as, without limitation, an ablation type, a power level at which ablation is to be performed, an ablation duration timer, and other similar information known in the art as associated with ablation procedures.

FIG. 2, is a schematic diagram of a computing device 200 that may be employed according to various embodiments of the present disclosure. Though not explicitly shown in the corresponding figures of the present application, the computing device 200, or one or more components thereof, may represent one or more components (e.g., workstation 102, simulator 106, simulated microwave ablation probe 112, simulated ultrasound wand 114, etc.) of the training system 100. The computing device 200 may include one or more processors 202, memories 204, display devices or displays 212, input modules, 214, output modules 216, and/or network interfaces 218, or any suitable subset of components thereof.

The memory 204 includes non-transitory computer readable storage media for storing data and/or software having instructions that may be executed by the one or more processors 202 and which, when executed, control operation of the computing device 200. More particularly, the memory 204 may include one or more solid-state storage devices such as flash memory chips. Additionally, or alternatively, the memory 204 may include one or more mass storage devices connected to the processor 202 through a mass storage controller and a communications bus (not shown). Although the description of computer-readable media described in this disclosure refers to solid-state storage devices, it will be understood that computer-readable storage media may include any available media that can be accessed by the processor 202. More particularly, computer-readable storage media may include non-transitory, volatile and/or non-volatile, removable and/or non-removable media, and the like, or any suitable combination thereof, implemented in any method or technology for storage of information such as computer readable instructions, data structures, program modules, or other suitable data access and management systems. Examples of computer-readable storage media include RAM, ROM, EPROM, EEPROM, flash memory, or other known solid state memory technology. Additionally, computer readable storage may include CD-ROMs or other such optical storage, magnetic cassettes, magnetic tape, magnetic disk storage, other magnetic storage devices, or any other medium which may be used to store information and which can be accessed by computing device 200.

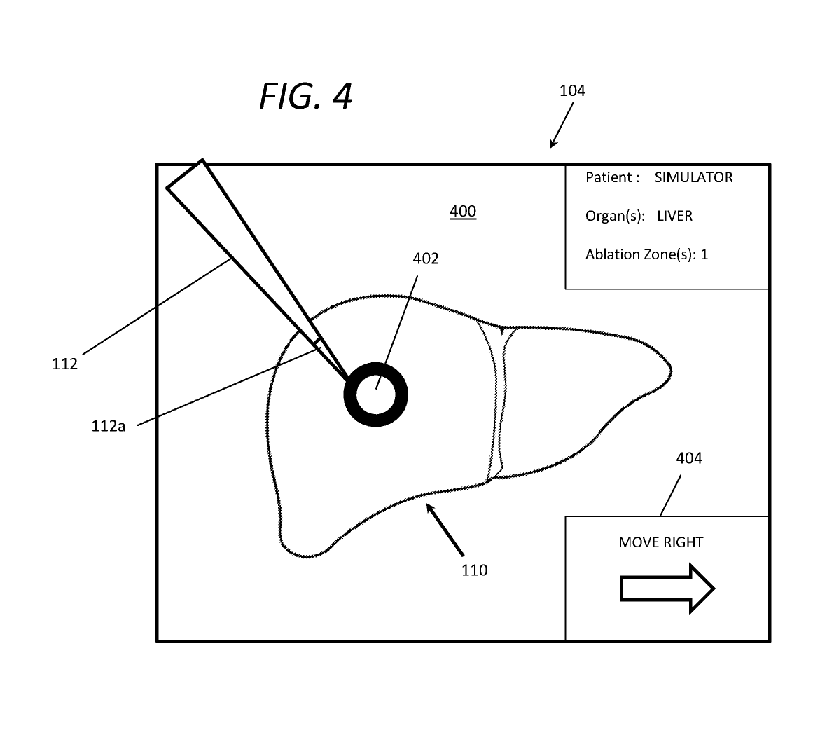

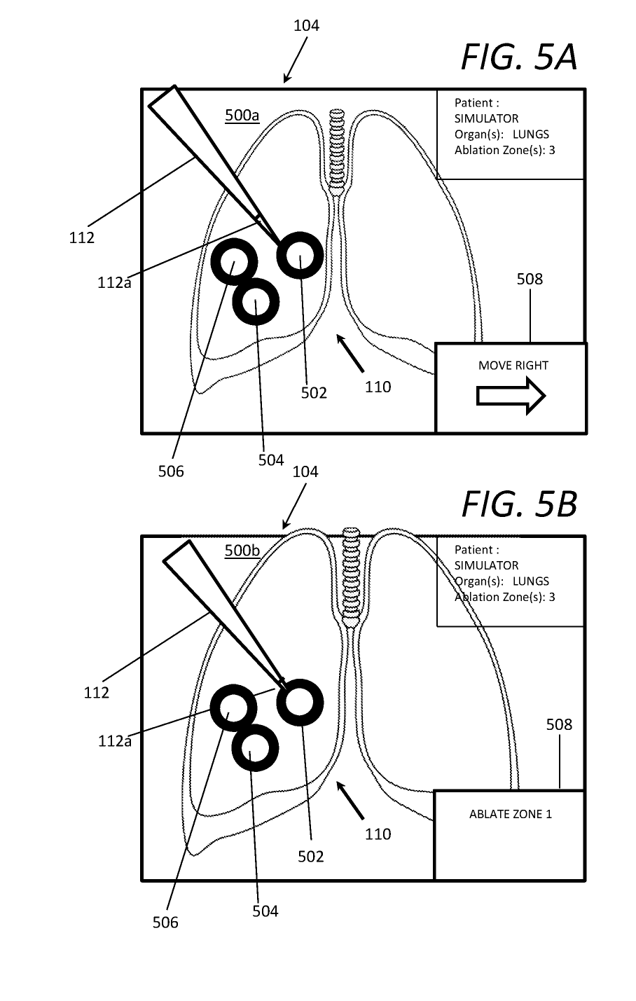

In embodiments, the memory 204 stores data 206 and/or one or more applications 208. Such applications 208 may include instructions which are executed on the one or more processors 202 of the computing device 200. In aspects, the application 208 may include instructions which cause a user interface component 210 to control the display 212 such that a user interface 210 is displayed (e.g., a graphical user interface (GUI) (see FIGS. 4, 5A, 5B). The network interface 218 may be configured to couple the computing device 200 and/or individual components thereof to a network such as a wired network, a wireless network, a local area network (LAN), a wide area network (WAN), a wireless mobile network, a Bluetooth® network, the Internet, and the like. The input module 214 may be any suitable input device or interface which may be engaged by a user for the entry of input data. For example, the input module 214 may include any combination of a mouse, a keyboard, a touch-capacitive display, a voice interface, or other such suitable devices known in the art. The output module 216 may include any connectivity port or bus such as, for example, a parallel port, a serial port, a universal serial bus (USB), or any other similar connectivity port known in the art. The input module 214 and output module 216 may also include wireless communication devices, such as an antenna (not shown), capable of establishing electrical communication with input devices (e.g., the simulated microwave ablation probe 112 and the simulated ultrasound wand 114) and output devices (e.g., the display 104 of the workstation 102, or any other display 212 and/or audio output device in electrical communication with the computing device 200).

Referring again to FIG. 1, the workstation 102 may have training software stored as an application 208 in the memory 204 of the workstation 102. The workstation 102 may have additional software or instructions stored therein which may be executed while the workstation 102 is in use. When the application 208, stored in the memory 204, is executed on the processor 202 of the workstation, the application 208 may control the display 104 to cause the display 104 to output one or more visual and/or audible outputs (e.g., a series of images, a video stream, or sound to speakers integrated into the display 104 (not shown)). More particularly, the images to be displayed may include, without limitation, ultrasound images, simulated ultrasound images, CT images, simulated CT images, three-dimensional (3D) models, and other predetermined user-interfaces associated for biopsy and ablation planning. The visual and/or audible output may be transmitted by the workstation 102 for display on the display 104 in response to input, such as positional data and/or a device state of either the simulated microwave ablation probe 112 and/or the simulated ultrasound wand 114 (see FIGS. 4-5B).

The workstation 102 may display multiple views (e.g., a pre-scanned CT image and a simulated CT image) on the display 104 of the workstation 102 so as to enable the clinician to assist the clinician during navigation and/or during the performance of an ablation procedure. Additionally, or alternatively, the workstation 102 may, based on the reception of position information related to the simulated ultrasound wand 114, generate an ultrasound image or series of ultrasound images and display the images in conjunction with CT images. In addition to image data generated based on CT image data as well as simulated ultrasound image data, the workstation 102 may display navigational aids 404, 508 (FIGS. 4-5B), surgery specific data, information input during pre-operative planning (e.g., power levels for performing ablation, recommended ablation times, etc.) and the like.

Additionally, an application 208 may be stored in the memory 204 of the workstation 102 for execution thereon associated with navigation through tissue or lumens of a body. Examples of such applications 208 may be found in U.S. Patent Application Publication No. 2016/0038247 to Bharadwaj, et al. entitled “Treatment Procedure Planning System and Method,” filed on Aug. 10, 2015, as well as U.S. Patent Application Publication No. 2016/0317229 to Girotto, et al. entitled “Methods for Microwave Ablation Planning and Procedure,” filed on Apr. 15, 2016, the entire contents of both of which are hereby incorporated by reference in their entirety.

The workstation 102 may, similar to the simulated microwave ablation probe 112 and the simulated ultrasound wand 114, be in either wired or wireless electrical communication via a connection 116 with the simulator 106. While the simulated microwave ablation probe 112 and the simulated ultrasound wand 114 are shown as connected to the workstation 102 via connections 116, the simulated microwave ablation probe 112 and the simulated ultrasound wand 114 may additionally or alternatively be coupled to the simulator 106. The simulator 106 may include one or more applications stored in the memory 204 of the simulator 106 which, when executed on the processor 202 of the simulator 106, control the transmission of data to or from the simulator 106 to the workstation 102. Likewise, in embodiments the workstation 102 may be integrated, either in whole or in part, into the simulator 106 such that the simulator 106 displays outputs similar to those described above during the simulated surgical procedures.

The simulator 106 includes a base 108 and a phantom 110 disposed thereon. The base 108 may include connectivity ports (not shown) which couple to the connections 116 associated with the simulated microwave ablation probe 112, simulated ultrasound wand 114, and/or workstation 102. Additionally, the base 108 may include any or all of the components described with respect to the computing device 200 of FIG. 2 to enable communication and control of the phantom 110, the simulated microwave ablation probe 112 and/or the simulated ultrasound wand 114 wirelessly via one or more antennas or other suitable wireless interface devices (not explicitly shown) associated with the input module 214 and/or the output module 216.

The phantom 110 may be formed in any suitable shape so as to resemble tissue which would, during a typical surgical procedure, be acted upon by the clinician with a microwave ablation probe and an ultrasound wand. For example, the phantom 110 may be formed in the shape of a liver to approximate corresponding visual representations of the internal structure of the anatomic feature visually approximated by the workstation 102 (see FIG. 4) or a pair of lungs (FIGS. 5A, 5B), which anatomically approximate living or ex-vivo organs. The phantom 110 may further include a bellow 110c (FIG. 1) or other such suitable components capable of manipulating the phantom 110 (e.g., expanding and contracting the exterior surface of the phantom 110) which, during operation, cause the phantom 110 to move during simulated surgeries (e.g., a lung or pair of lungs may expand and contract, thereby simulating breathing). It is contemplated that, in embodiments, one or more bellows 110c may be selectively placed within the phantom 110 and configured to selective engage portions of the phantom to approximate motion in select portions of the represented organ (e.g., a portion of a lung may be caused to expand and contract, thereby simulating an organ which is not functioning as expected). The phantom 110 may be formed of a solid substance (such as hard rubber or acrylics), a semi-solid substance (e.g., may contain an inner-skeleton to approximate the form of an organ while being surrounded in a coating or skin made of a pliable material such as rubber), foam, or any other suitable porous or non-porous material.

An EM field generator 110a may be disposed either in or on the base 108 or beneath the phantom 110 so as to generate an EM field for capturing the position of one or more EM sensors in proximity to, or disposed on, the simulator 106. The phantom 110 may also have one or more EM reference sensors 110b disposed either internal or external to the phantom 110 which capture the pose of the phantom 110 intermittently or continuously during the simulated surgical procedure. In response to the generation of the EM field, a tracking module (not explicitly shown) may receive signals from each of the EM reference sensors 110b, 112a, 114a and, based on the signals, derive the location of each EM reference sensor 110b, 112a, 114a in six degrees of freedom. In addition, one or more reference sensors may be disposed in fixed relation relative to the phantom 110. Signals transmitted by the reference sensors to the tracking module may subsequently be used to calculate a patient coordinate frame of reference. Registration is generally performed by identifying select locations in both the stored representation of the anatomical feature associated with the phantom 110 and the reference sensors disposed along the phantom 110. For a detailed discussion of similar registration techniques, reference may be made to U.S. Patent Application Publication No. 2011/0085720, entitled “AUTOMATIC REGISTRATION TECHNIQUE,” filed by Averbuch on May 14, 2010, the contents of which are hereby incorporated by reference in their entirety. In addition to the components disclosed here, an ablation EM sensor 112a and an ultrasound EM sensor 114a are disposed on the simulated ablation probe 112 and simulated ultrasound wand 114, respectively. In embodiments during which a simulated broncoscopic procedure is simulated, the ablation EM sensor 112a is disposed along a distal portion of an extended working channel (“EWC”) of a simulated broncoscopy probe, and an ultrasound EM sensor 114a is disposed along a distal portion of the simulated ultrasound wand 114. Additionally, in embodiments, the ablation EM sensor 112a and the ultrasound EM sensor 114a may include an array of EM sensors (not shown) disposed along the respective device, so as to provide a more accurate positional measurement of the device. Collectively, for clarity the EM components disclosed herein will be referred to as the EM tracking system 109.

The EM tracking system 109, during operation, transmits signals to the workstation 102 to indicate the pose of any one of the EM reference sensors 110b, the ablation EM sensor 112a, and the ultrasound EM sensor 114a, referred to collectively as the EM sensors. The workstation 102, in response to receiving signals from the EM tracking system 109, determines a pose for each of the instruments associated with particular EM sensors. It will be understood that the EM tracking system 109 may measure or determine the position of any of the included instruments within three-dimensional space and further within proximity of the EM field generator 110a, thereby enabling the EM tracking system 109 to determine the position and orientation of the relevant components to the phantom 110 during the simulated surgical procedure.

In embodiments where the simulated ablation probe 112 does not pierce or otherwise extend through the exterior surface of the phantom 110 during a simulated surgical procedure, the simulated ablation probe 112 may have one or more force sensors (not explicitly shown) configured to engage the surface of the phantom 110. More particularly, the simulated ablation probe 112 may have a shortened distal portion which is configured to engage the phantom 110 When the simulated ablation probe 112 is pressed against the exterior surface of the phantom 110, by virtue of the shortened length of the distal portion of the probe 112, the clinician engaging the simulated ablation probe 112 may feel as if the probe were inserted into the anatomical feature represented by the phantom 110 even though no portion of the probe 112 may be piercing or otherwise extending beyond the surface of the phantom 110. Based on force measurements transmitted by the force sensor to the workstation 102, the workstation 102 may determine the position at which the simulated ablation probe 112 would be within the anatomical feature based on the force applied by the simulated ablation probe 112 to the exterior or outer surface of the phantom 110. The workstation 102 may then generate a virtual representation of an ablation probe based on the force measurements and position of the simulated ablation probe 112 relative to the phantom 110.

According to embodiments, during simulated surgical procedures, the workstation 102 simulates ultrasound and/or CT images on the display 104 which similar to those expected during a typical surgical procedure. For example, one or more surgical simulation applications or application 208 (FIG. 2) may, based on the determined pose of the phantom 110, the simulated ablation probe 112 and the simulated ultrasound wand 114, relative to one another, display the position of the distal portion of the simulated ablation probe 112 relative to the phantom 110 (FIGS. 4-5B). The application 208 may simulate the various phases of a surgical procedure, including the generation of one or more 3D models during a planning phase or during the simulated surgical procedure, (e.g., identifying target locations and planning a pathway to the target locations during planning), registering either stored or generated 3D models with the phantom 110 (e.g., calibrating the simulator for use with a phantom liver (FIG. 4), lung (FIGS. 5A, 5B), etc.), navigation during a simulated surgical procedure to the target location or locations, performance of ablation at the target location or locations, and the like. Models of anatomical features represented by the phantom 110 may be generated and stored either in a library of standard models (which include an average representation of an anatomical feature). Alternatively, if pre-operative scan data is available such as computed tomographic (CT), magnetic resonance imaging (MRI), X-ray, cone beam computed tomography (CBCT), and/or positron emission tomography (PET) scan data, 3D models may be generated by the workstation 102, prior to or during a simulated surgical procedure, so as to simulate a surgical procedure on a scanned anatomic feature.

During simulated surgical procedures, the application 208 may cause the display 104 to illustrate the position of the distal portion or distal tip of the simulated ablation probe 112 relative to the target location 402 (FIG. 4) of an anatomical feature as would be illustrated during typical percutaneous and/or subcutaneous navigation. For example, during a typical surgical procedure, to avoid providing clinicians with latent or otherwise undesired indication of the position of the simulated ablation probe 112 or other surgical instruments relative to the target location (FIGS. 4-5B; 402, 502-506), the workstation 102 may continuously superimpose the position of the simulated ablation probe 112 onto the 3D model of the anatomic feature. By superimposing the position of the ablation probe onto the 3D model, the anatomical feature as well as the position of the simulated ablation probe 112 relative to the anatomical feature may be updated in the memory 204 and on the display 104 of the workstation 102 without reflecting any gaps, or other imperfections in the sensor data associated with the anatomical feature and/or the simulated ablation probe 112. Where gaps become too great (e.g., a positional signal is not received for a predetermined period), the application 208 may cause the display 104 of the workstation 102 to display a warning (e.g., “SIGNAL ERROR”). Similarly, during a simulated surgical procedure, the application 208 may simulate such conditions (e.g., signal loss, signal errors, etc.) and cause the display to output information indicating such. For a more detailed description of planning and navigation software, reference may be made to U.S. Pat. Nos. 9,459,770, and 9,639,666 and U.S. Patent Application Publication No. 2014/0270441, filed by Baker et al. on Mar. 15, 2013, and entitled “PATHWAY PLANNING SYSTEM AND METHOD,” the contents of each of which are hereby incorporated by reference in their entirety; as well as U.S. Pat. No. 9,770,216, entitled “SYSTEM AND METHOD FOR NAVIGATING WITHIN THE LUNG,” filed on Jun. 29, 2015, by Brown et al., the entire contents of which are hereby incorporated by reference in their entirety.

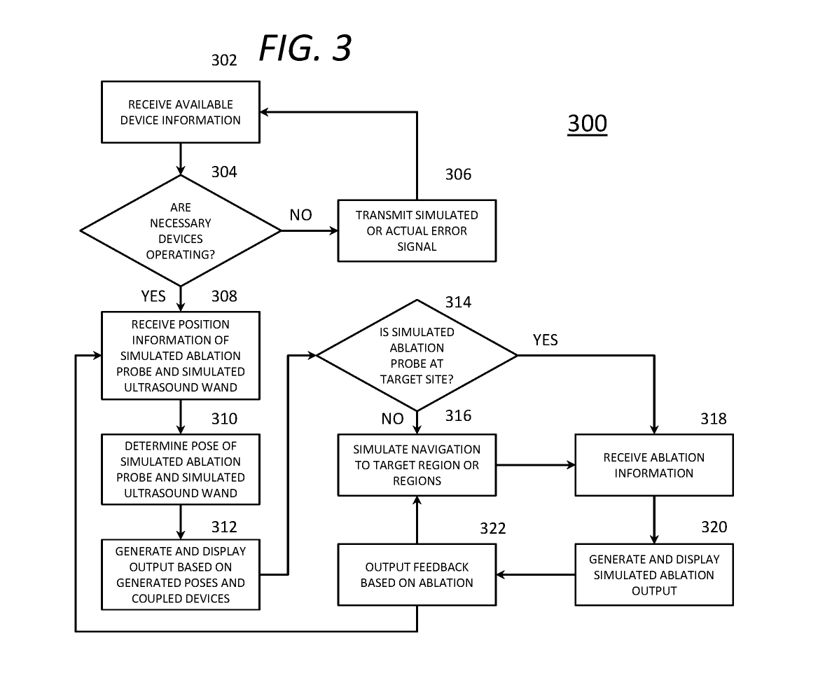

Referring now to FIG. 3, illustrated is a flowchart depicting an illustrative method for simulating surgical procedures with a training system 100 (FIG. 1) in accordance with certain embodiments of the present disclosure, the method designated generally process 300. Process 300, and associated techniques described herein, enable visual simulation of a simulated surgical procedure via the display 104 of the training system 100 (FIG. 1). While process 300 is described with reference to a particular sequence of steps, it will be apparent to one skilled in the art that certain steps described may be concurrently executed, or executed out of the sequence explicitly disclosed herein, without departing from the scope of the present disclosure. Additionally, or alternatively, steps of process 300 may be modified, removed, etc., without departing from the scope and spirit of the present disclosure.

Process 300 generally discloses a manner in which targeted ablation procedure is simulated. The simulated procedure may begin at block 302 where the workstation 102 receives information from devices (e.g., the simulator 106, the simulated ablation probe 112, and the simulated ultrasound wand 114) such as a device ID or other information to identify the devices, as well as the operational state of the devices (e.g., operational, low battery, non-functional, etc.) Once the workstation 102 receives the device information from the connected devices, the workstation 102 determines whether the necessary devices for performing the simulated procedure are connected and operational at block 304. If any of the devices in communication with the workstation 102 indicate that either they are non-functional or not ready to be used to perform the simulated surgical procedure, the workstation 102 causes the display 104 to output a relevant error message, including a message that certain devices are not connected, or are not operating properly at block 306. The process 300 may reiterate this process until it is determined that the training system 100 is ready for use.

In embodiments, though the clinician operating the training system 100 may have appropriately associated the devices with the workstation 102, the workstation 102 may continue to cause the display 104 to transmit an error code via the display 104 to simulate an error with either the workstation 102, the simulator 106, or one of the devices (e.g., the simulated microwave ablation probe and/or the simulated ultrasound wand 114.) For example, during the initial stages of a simulated surgical procedure, the clinician may couple the simulated microwave ablation probe 112 to the workstation 102. To prompt the clinician to check the simulated ablation probe 112, the workstation 102 may output a message “ANTENNA ERROR,” which would, during a real surgical procedure, indicate that the antenna of an ablation probe is damaged or disconnected. Once the clinician resets the simulated ablation probe 112, the workstation 102 may cause the display to transmit a message indicating that the error was resolved. In embodiments, the workstation 102 may also recognize that the simulated ablation probe 112 selected by the clinician is not appropriate for the type of tissue or phantom 110 coupled to the simulator 106, and output a warning message to indicate the mismatch.

When the workstation 102 determines that the appropriate devices are present, process 300 continues and the workstation 102 receives position information related to the position of the simulated ablation probe 112, the simulated ultrasound wand 114, and the phantom 110 relative to one another (block 308). More particularly, as discussed above, the EM tracking system 109 may capture signals from the EM reference sensors 110b, the ablation EM sensor 112a, and the ultrasound EM sensor 114a based on operation of the EM tracking system 109, thereby indicating the position of the phantom 110, simulated microwave ablation probe 112, and simulated ultrasound wand 114 relative to the EM field generator 110a. Based on the position information, the workstation 102 may calculate the pose of each of the phantom 110, the simulated microwave ablation probe 112, and the simulated ultrasound wand 114 at block 310.

In embodiments, at block 308 the workstation 102 may receive sensor information from any of the earlier instrument tracking systems mentioned to determine the position of the simulated ablation probe 112 and/or the simulated ultrasound wand 114. For example, one or more optical imaging sensors and/or depth sensors may be positioned to image the simulator 106 during simulated surgical procedures. The optical imaging sensors and/or depth sensors may identify the pose of the simulated ablation probe 112 and/or the simulated ultrasound wand 114 relative to the simulator 106 and, based on the identification, transmit sensor signals to the workstation 102 indicative of the pose of the simulated ablation probe 112 and/or the simulated ultrasound wand 114 relative to the simulator 106.

In embodiments, imaging devices (e.g., a portable CT imaging device) may be used to image the phantom 110. The imaging devices may capture position-identifying information such as, without limitation, markers disposed about the phantom 106, the simulated ablation probe 112, and/or the simulated ultrasound wand 114. The imaging devices may then transmit the captured image information to the workstation 102 which registers the position of the markers, and their respective device, to determine the pose of each device relative to the phantom 110.

At block 312, the workstation 102 generates an image or images to be displayed on the display 104 indicative of the positions of the simulated ablation probe 112 and the simulated ultrasound wand 114 relative to the phantom 110. More particularly, the workstation 102 first calculates the pose of the simulated ultrasound wand 114 relative to the phantom 110. As would be the case in a surgical procedure, an image of the anatomical feature represented by the phantom 110 is generated based on the position of the simulated ultrasound wand 114 relative to the phantom 110. To approximate the visual representation of an ablation probe relative to the anatomical structure for display, the workstation 102 generates an image of the anatomical feature represented including the representation of a surgical device based on the pose of the simulated microwave ablation probe 112 and the simulated ultrasound wand 114 relative to the phantom 110.

If the workstation 102 determines that the simulated ablation probe 112 is not positioned or has not, over the course of the simulated procedure, been advanced to a target site at block 314, the workstation may overlay elements onto the generated display at block 316 such as navigational aids 404, 508, (FIGS. 4-5B) which assist the clinician in advancing the simulated ablation probe 112 to the target ablation site. The navigational aids 404, 508, 509 may be displayed until the simulated ablation probe 112 is in position, e.g., is at the target region (FIGS. 4-5B; 402, 502, 504, 506). Once at the target location 402, 502, 504, 506, at block 318 the clinician may input information which is received either by the simulated ablation probe 112 or a simulated electrosurgical generator (not explicitly shown) which is transmitted to the workstation 102. The information received by the simulated ablation probe 112, or simulated electrosurgical generator, may include selection of a power setting (e.g., the desired wavelength at which an ablation probe would be set for the ablation of the target area) or any other known ablation setting which would normally be adjustable by the clinician during an ablation operation. Receiving ablation information may further include input by the clinician to initiate the beginning of, or end, the delivery of ablative energy to the target area (e.g., turning on and off the simulated ablation probe 112). If no ablation information is received by the workstation at block 318, the workstation 102 may simulate the ablation procedure as occurring in a predetermined manner, e.g., based on default ablation settings.

At block 320 the workstation 102 generates an image or series of images (see FIGS. 4-5B) to be displayed on the display 104 to approximate the visual representation which would otherwise be provided during an ablative surgical procedure. More particularly, the workstation 102 may, based on the parameters set for the simulated ablation probe 112 and information collected or simulated regarding the simulated anatomical feature, generate images (see FIGS. 4-5B) illustrating the generation of an ablation region along the anatomical feature. For example, as the user delivers user input by engaging the simulated ablation probe 112 to cause the simulated ablation probe 112 to ablate or otherwise act on target tissue, the workstation 102 may generate images to visually represent tissue as the tissue receives ablative energy. Once the images are generated, and the ablation of the target site completed, process 300 may be repeated by returning to block 308 and advancing the simulated ablation probe 112 to a different target site.

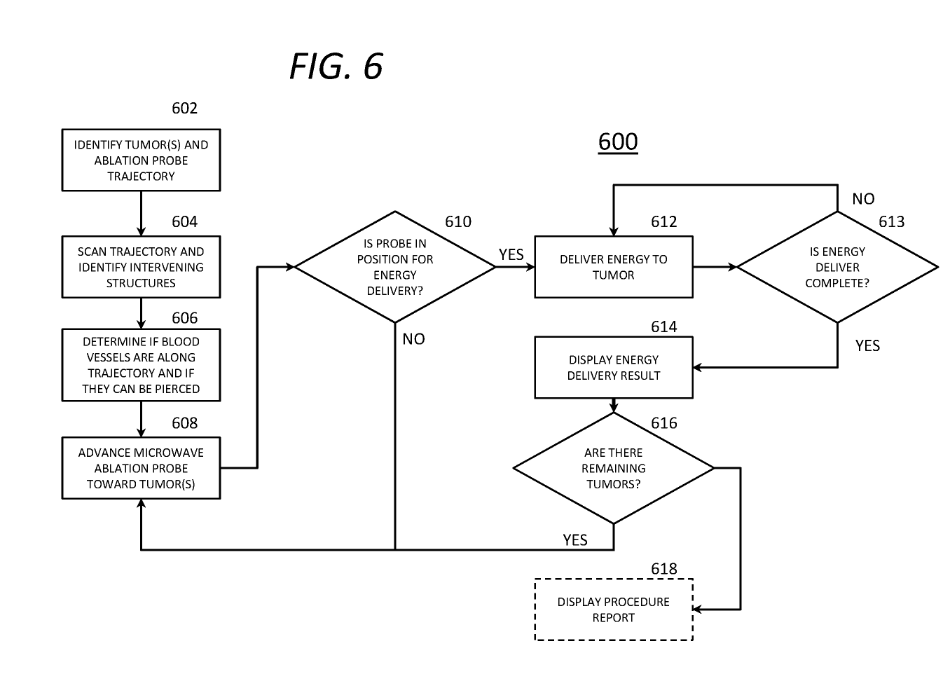

Optionally, at block 322, the workstation 102 may determine whether an ablation task has been completed. More particularly, based on engagement by the clinician with the training system 100, the workstation 102 may determine whether certain navigation and/or ablation objectives have been completed, and if not, to what degree the objectives were completed. For example, if the clinician engaging the training system 100 engages the workstation 102 to cause the workstation to ablate sixty-percent of a target region, the workstation 102 may prompt the clinician to continue to ablate the target region by indicating that only sixty-percent of the target region has received sufficient simulated ablative energy. An example training session is discussed in greater detail with reference to FIG. 6.

FIG. 6 illustrates another manner in which targeted ablation procedure is simulated, referred to generally as process 600. Initially, at block 602 based on either fabricated simulation data (e.g., a predefined organ model having growths or tumors therein to be ablated during the simulated ablation procedure) or actual three-dimensional scans (e.g., CT scans) of an organ of a patient having tumors or growths therein (referred to herein as a “a simulated organ”) a clinician reviews the simulated organ and identifies the tumors located therein to be ablated, as well as a trajectory along which an ablation probe would be advanced during an ablation procedure. At block 604 the clinician then identifies any intervening structures which would be engaged by an ablation probe if the trajectory were to be followed during the ablation procedure. At block 606, the clinician determines whether the structures (e.g., blood vessels, etc.) should be pierced or if the trajectory should be amended so as to avoid the structures, thereby completing the planning for the procedure.

The workstation 102, based on the clinician input associated with the identification of tumors, trajectory, and intervening structures which would be affected by the ablation trajectory, may store the information input by the clinician for subsequent recall and/or display in the memory 204 of the workstation 102 during additional pre-operative or post-operative review of a simulated surgical procedure. For example, once the trajectory is identified, the workstation 102 retrieve the stored information from the memory 204 and cause the display 104 to show scanned CT image data, simulated ultrasound images having a trajectory overlaid thereon, and navigational aids. The workstation 102 may also store information collected during the simulated surgical procedure in the memory 204 of the workstation 102 such as, without limitation, images generated during the simulated surgical procedure, audio collected by a microphone (not shown), etc.

At block 608, the clinician begins the simulated surgical procedure by advancing the simulated ablation probe 112 toward the first tumor along the predetermined trajectory during a navigation phase of the simulated surgical procedure (and toward subsequent tumors if any are determined to remain at block 616). Prior to advancing the simulated ablation probe, the workstation 102 may, based on the type of probe (e.g., the length, width, energy delivery type, etc.) the workstation 102 may output an error indicating that there is a probe mismatch or that the probe is otherwise inappropriate for the ablation procedure being performed.

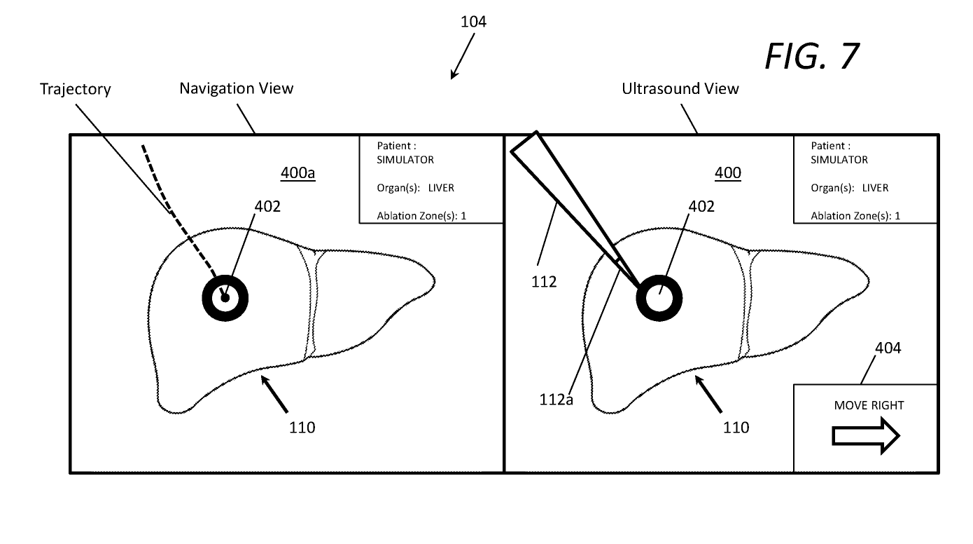

As the clinician advances the simulated ablation probe 112 toward the tumor, the workstation receives position information from the simulated ablation probe 112, the simulated ultrasound probe 11, and, optionally, the surface of the phantom 110. Based on the received position information, the workstation 102 generates and causes the display 104 to display a representation of an ultrasound image during the simulated ablation procedure (see FIGS. 4, 5A, and 5B). For example, the workstation 102 may cause the display 104 to display a simulated image of the simulated ablation probe 112 as advanced along the trajectory toward the tumor. In embodiments, the workstation 102 may cause the display 104 to show multiple views such as, without limitation, a navigation view (see FIG. 7, 500c) where a predetermined navigation path is overlaid onto the pre-operative CT scan of the anatomic feature, as well as a simulated ultrasound view of the current position of the simulated ultrasound probe 112 relative to the anatomic feature (FIG. 7). As the clinician navigates the simulated ablation probe 112 toward the tumor, the workstation 102 continuously updates the display to include updated position information and updated navigational aids 404, 508. If the workstation 102 determines that the simulated ablation probe 112 is not in position to deliver energy to the tumor, navigation continues. Alternatively, if the workstation 102 determines that the simulated ablation probe 112 is in position, the simulated ablation probe 112 may be activated by the clinician to deliver energy to the target tissue at block 612. As energy is delivered, the workstation 102 displays a timer (not shown) on the display 104 indicating the amount of time remaining for energy delivery of that particular tumor based on the predetermined amount of time and/or amount of energy to be delivered to that tumor. Once it is determined that energy is delivered for a predetermined amount of time (block 613) the result of the energy delivery is displayed at block 614, as well as optional results (e.g., was the delivery effective, to what extent was the tumor ablated, etc.). If any tumors are determined to remain (block 616), process 600 continues to block 608, navigating toward the next tumor to perform ablation. Alternatively, and optionally, once the workstation determines that there are no remaining tumors at block 616, an ablation report may be displayed at block 618.

Throughout process 600, feedback may be output via the display 104 to the clinician to indicate the progress of the navigation and ablation procedure to the clinician. For example, the workstation 102 may collect information such as the pressure exerted by the clinician on the simulated ablation probe 112, the pose of the simulated ablation probe 112 relative to the phantom 110, and ablation procedure information such as the duration and energy level at which the tumors were ablated during the procedure. Based on this procedural information, the workstation 102 may display information to indicate that more or less pressure was necessary, that energy was not delivered at a sufficient energy level to completely ablate the target tissue, or, similarly, for a sufficient duration, etc. Additionally, feedback may be given to indicate whether the clinician advanced the probe along the desired path, or, if not, to what extent the probe disembarked from the predetermined trajectory.

At block 618, information associated with the simulated ablation procedure is output to the clinician. The information may include any of the optional information noted above. Additionally, the simulated procedure may be played back for the clinician to review and store for subsequent review by the clinician and others.

While the above-described systems, devices, and methods are described with reference to simulated percutaneous EMN procedures, it will be appreciated by those skilled in the art that the same or similar devices, systems, and methods may be used to perform ablation by navigating through pathways of the body. For example, in the case where the phantom 110 represents an airway and lungs, having bronchial paths leading to a left and right lung (see FIGS. 5A, 5B, navigation of the simulated ablation probe 112 through a breathing pathway may be simulated based on the position of the simulated ablation probe 112 relative to the phantom 110 and the simulated ultrasound wand 114. As noted above, in embodiments introduction of the simulated ablation probe 112 may include introduction of a bronchoscope into pathways of the phantom 110 which approximate the bronchial structures of a patient. Such simulated introduction of a bronchoscope may include illustrating a two-dimensional view of the region of the body and associated anatomical features in which the simulated bronchoscope is disposed captured by a camera disposed along a distal portion of the EWC of the simulated bronchoscope. In addition to bronchial navigation, the workstation 102 may control a breathing simulation system enclosed within the phantom 110. The breathing simulation system may include a bellow 110c (FIGS. 5A, 5B) which causes the phantom 110 to expand and contract, thereby more accurately simulating navigation through the lungs of a patient. Additionally, the training system 100 may continuous update the 3D image of the lungs to be shown on the display 104 in response to movement of the EM reference sensors 110b while the bellow 110c expands and contracts. For a detailed description of systems and methods of navigating which may be employed in accordance with embodiments of the present disclosure, reference may be made to U.S. Pat. No. 9,770,216 entitled “System and Method for Navigating Within the Lung,” the contents of which are hereby incorporated by reference in their entirety.

Referring now to FIGS. 4, 5A, 5B, and 7, illustrated are various user interfaces which may be displayed on the display 104 (FIG. 1) of the workstation 102 during simulated procedures. As noted above, FIGS. 4, 5A, and 5B include images generated by the workstation 102 to illustrate a simulated ultrasound images 400, 500a, 500b during the simulated procedure. The simulated ultrasound image 400 includes a visual representation of the simulated ablation probe 112 relative to an anatomical feature (e.g., a liver) as the simulated ablation probe 112 is advanced through the anatomical feature by the clinician. The simulated ultrasound image 400 includes navigation aids 404 which are generated during the simulated procedure to indicate to the clinician the direction in which the simulated ablation probe 112 should be advanced to engage the target tissue. The simulated ultrasound images 400, 500a, 500b are generated based on the sensed position and orientation of the simulated ablation probe 112 and the simulated ultrasound wand 114 relative to the phantom 110.

Similar to FIGS. 4, 5A, and 5B, FIG. 7 includes an alternative output displayed by the display 104 (FIG. 1) during a simulated surgical procedure. Specifically, the generated ultrasound image of FIG. 4 is paired with a navigation view of a CT image 400a including a trajectory. The workstation 102 may align the images as desired for output on the display 104 (e.g., side-by-side, as an overlay, a picture-in-picture view, etc.) so depending on the particular procedure or desire of the clinician. The trajectory may further indicate where the simulated ablation probe 112 is relative to the anatomical feature represented by the phantom 110 to indicate the progression of the simulated ablation probe 112 during the simulated procedure. While FIGS. 4, 5A, 5B, and 7 illustrate particular display outputs, it is contemplated that any of the information disclosed herein may be displayed as desired by the clinician, or if predetermined, according to the predetermined layout.

The term “clinician” refers to doctors, nurses, or other such support personnel that may participate in the use of the simulation systems disclosed herein; as is traditional, the term “proximal” refers to the portion of a device or component which is closer to the clinician whereas the term “distal” refers to the portion of the device or component which is further from the clinician. In addition, terms such as front, rear, upper, lower, top, bottom, and other such directional terms are used to aid in the description of the disclosed embodiments and are not intended to limit the present disclosure. Well-known functions or constructions are not described in detail so as to avoid obscuring the present disclosure unnecessarily.

While detailed embodiments of devices, systems incorporating such devices, and methods of using the same are described herein, these embodiments are merely examples of the subject-matter of the present disclosure, which may be embodied in various forms. Therefore, specifically disclosed structural and functional details are not to be interpreted as limiting, but merely as providing a basis for the claims and as a representative basis for allowing one skilled in the art to variously employ the present disclosure in appropriately detailed structure. Those skilled in the art will realize that the same or similar devices, systems, and methods as those disclosed may be used in other lumen networks, such as, for example, the vascular, lymphatic, and/or gastrointestinal networks as well. Additionally, the same or similar methods as those described herein may be applied to navigating in other parts of the body, such as the chest areas outside of the lungs, the abdomen, pelvis, joint space, brain, spine, etc.

The embodiments disclosed herein are examples of the disclosure and may be embodied in various forms. For instance, although certain embodiments are described as separate embodiments, each of the embodiments disclosed may be combined with one or more of the other disclosed embodiments. Similarly, references throughout the present disclosure relating to differing or alternative embodiments may each refer to one or more of the same or different embodiments in accordance with the present disclosure.

Any of the herein described methods, programs, algorithms or codes may be converted to, or expressed in, a programming language or computer program. The terms “programming language” and “computer program,” as used herein, each include any language used to specify instructions to a computer, and include (but is not limited to) the following languages and their derivatives: Assembler, Basic, Batch files, BCPL, C, C+, C++, Delphi, Fortran, Java, JavaScript, machine code, operating system command languages, Pascal, Perl, PL1, scripting languages, Visual Basic, metalanguages which themselves specify programs, and all first, second, third, fourth, fifth, or further generation computer languages. Also included are database and other data schemas, and any other meta-languages. No distinction is made between languages which are interpreted, compiled, or use both compiled and interpreted approaches. No distinction is made between compiled and source versions of a program. Thus, reference to a program, where the programming language could exist in more than one state (such as source, compiled, object, or linked) is a reference to any and all such states. Reference to a program may encompass the actual instructions and/or the intent of those instructions.

Any of the herein described methods, programs, algorithms or codes may be contained on one or more machine-readable media or memory. The term “memory” may include a mechanism that provides (e.g., stores and/or transmits) information in a form readable by a machine such a processor, computer, or a digital processing device. For example, a memory may include a read only memory (ROM), random access memory (RAM), magnetic disk storage media, optical storage media, flash memory devices, or any other volatile or non-volatile memory storage device. Code or instructions contained thereon can be represented by carrier wave signals, infrared signals, digital signals, and by other like signals. It should be understood that the foregoing description is only illustrative of the present disclosure. Various alternatives and modifications can be devised by those skilled in the art without departing from the disclosure. Accordingly, the present disclosure is intended to embrace all such alternatives, modifications and variances. The embodiments described with reference to the attached drawing figures are presented only to demonstrate certain examples of the disclosure. Other elements, steps, methods, and techniques that are insubstantially different from those described above and/or in the appended claims are also intended to be within the scope of the disclosure.

What is claimed is:

1. A system for performing simulated ablation procedures, the system comprising:
a simulated ablation probe;
a simulated imaging device;
a phantom configured to be engaged by the simulated ablation probe and the simulated imaging device, the phantom representing an anatomical feature; and
a workstation in electrical communication with the simulated ablation probe, the simulated ultrasound imaging device, and the phantom, the workstation configured to generate and display an image including a representation of the anatomical feature represented by the phantom,
wherein the image further includes data associated with a position of the simulated ablation probe relative to the representation of the anatomical feature represented by the phantom.

2. The system of claim 1, wherein the simulated imaging device is either a simulated ultrasound imaging device or a simulated CT scanner.

3. The system of claim 1, wherein a portion of the phantom is configured to approximate a shape of the anatomical feature while the anatomical feature is functioning.

4. The system of claim 1, wherein the workstation generates the image based on the phantom and a pre-existing data set associated with the organ.

5. The system of claim 1, wherein the workstation receives imaging position information associated with the pose of the simulated imaging device relative to the phantom and, based on the imaging position information, generates a first updated image.

6. The system of claim 5, wherein the workstation receives probe position information associated with the pose of the simulated ablation probe relative to the phantom and, based on the probe position information, generates a second updated image.

7. The system of claim 6, wherein the workstation is configured to generate a third updated image including an ablation region formed along the anatomical feature based on the probe position information in response to user input indicating that ablation is to be performed by the simulated ablation probe.

8. The system of claim 6, wherein the workstation receives user input including at least one energy property selected from the group consisting of voltage, current, power, and impedance and, based on the at least one energy property, the probe position information, and an energy delivery duration, generates a third updated image including an ablation region formed along the representation of the anatomical feature.

9. The system of claim 6, wherein the workstation receives phantom position information indicating a position of the phantom relative to a base and, based on the position of the phantom, generates a third updated image.

10. The system of claim 9, wherein the phantom is configured to change shape so as to approximate the shape of the organ acting within a body.

11. The system of claim 6, wherein an EM sensor is disposed along a distal portion of both the simulated ablation probe and the simulated imaging device, and an electromagnetic (EM) field generator is disposed in proximity to the phantom, the EM field generator configured to generate an EM field, and the workstation configured to receive position information from the EM sensors disposed on the simulated ablation probe and the simulated imaging device.

12. The system of claim 11, wherein an EM sensor is disposed along the phantom and, in response to the generated EM field, the EM field generator is configured to receive position information from the EM sensor disposed along the phantom.

13. A workstation for simulating ablation procedures, the workstation comprising:
a processor; and
a memory coupled to the processor, the memory having instructions stored thereon which, when executed by the processor, cause the workstation to:
receive position information of a simulated imaging device and a simulated ablation probe positioned relative to a phantom associated with an organ;
generate an image including a representation of the organ associated with the phantom based on the position information of the simulated imaging device and the simulated ablation probe; and
transmit a signal to cause the image to be displayed on a display associated with the workstation,
wherein the image includes a representation of the simulated ablation probe relative to the representation of the organ associated with the phantom.

14. The workstation of claim 13, the memory further having stored thereon instructions that, when executed by the processor, cause the processor to:
receive position information of the phantom relative to a fixed point on the phantom,
wherein the generating includes generating the image based on the position information of the phantom.

15. The workstation of claim 14, wherein the receiving includes continuously receiving the position information of the simulated imaging device, the simulated ablation probe, and
wherein the generating includes continuously generating the image based on the continuously received position information of the simulated imaging device, the simulated ablation probe and the phantom.

16. A method of simulating a surgical procedure with an ablation training system, the method comprising:
receiving device information from a simulated ablation probe and a simulated imaging device;
receiving position information of the simulated ablation probe and the simulated imaging device relative to a phantom;
determining a pose of the simulated ablation probe and the simulated imaging device relative to the phantom; and
generating a display including a visual representation of the position of a simulated ablation probe relative to an anatomical feature based on the pose of the simulated ablation probe and the simulated imaging device.

17. The method of claim 16, wherein generating a display further includes overlaying a navigation plan onto the visual representation of the simulated ablation probe relative to the anatomical feature.

18. The method of claim 17, wherein overlaying the navigation plan further includes overlaying navigational aids onto the visual representation of the simulated ablation probe relative to the anatomical feature.

19. The method of claim 16, further comprising displaying a visual representation of the anatomical feature in response to receiving user input to ablate a target region.
